(19) United States
(12) Patent Application Publication
(10) Pub. No.: US 2014/0100802 A1
(43) Pub. Date: Apr. 10, 2014

(54) Method and computer system for measuring remaining battery capacity

(71) Applicant: ENERGY PASS INCORPORATION, Hsinchu City (TW)

(72) Inventors: Ming-Hsien Lee, Hsinchu City (TW); Chi-Yu Yang, Hsinchu County (TW)

(73) Assignee: ENERGY PASS INCORPORATION, Hsinchu City (TW)

(21) Appl. No.: 13/646,735

(22) Filed: Oct. 8, 2012

(51) Int. Cl. G01R 31/36

(52) U.S. Cl. 702/63; 324/426

(57) ABSTRACT

A method for measuring a remaining capacity of a chargeable magnetic material includes determining a discharging parameter, obtaining an open-circuit-voltage state-of-charge (OCV SOC) curve according to the discharging parameter, obtaining a discharging curve according to the OCV SOC curve and the discharging parameter, and processing an interpolation operation to measure the remaining capacity according to the OCV SOC curve and the discharging curve.

### BACKGROUND OF THE INVENTION

1. Field of the Invention

The present invention relates to a method and a computer system for measuring a remaining battery capacity, and more particularly, to a method and a computer system which utilizes an open-circuit-voltage state-of-charge curve and a discharging curve for measuring a remaining battery capacity.

2. Description of the Prior Art

Accompanying developments of mobile devices, it has become a popular issue to accurately estimate a state-of-charge (SOC) or a remaining capacity of a battery of a mobile device. Most of the mobile devices consume lots of power, especially for Internet wireless accessing. Some of the users will carry backup batteries, but it seems such a burden for convenient concerns. Also, purchase of the backup batteries may not be a long-term solution since the life span of the mobile device should be limited. The corresponding backup batteries of the mobile device will be abandoned once the mobile device is out of function/fashion. Accordingly, an effective battery management system (BMS) is necessary to provide the instantaneous SOC or remaining battery capacity of the mobile device to the users, so as to notice the users when they have to charge the battery or backup the processing information while they are far away from plug-in power sources with the limiting remaining capacity.

Generally, the BMS utilizes an open-circuit-voltage (OCV) table to represent the remaining capacity of the mobile device (battery). Please refer to FIG. 1, which is a schematic diagram of a conventional OCV simplified circuit 10. As shown in FIG. 1, the OCV simplified circuit 10 comprises resistors Rd, Ri and a capacitor Cd to simulate a simplified lithium-ion battery. After the OCV simplified circuit 10 is charged with an initial voltage source VS, a voltage value Vk is measured to correspondingly obtain a relationship between the OCV and the SOC. Please refer to FIG. 2, which illustrates a schematic diagram of a relationship curve between a plurality of OCV values and a plurality of SOC values according to the prior art. As shown in FIG. 2, the relationship curve is obtained via a charging operation as well as a discharging operation with 48 steps, which means that there are 47 points along the relationship curve to set up a look-up table for the OCV and the SOC. In detail, the simplified battery hereinafter is charged with a current of 0.1 C-rate to 4.1 V. Then, an interpolation method is operated for calculation and the simplified battery is discharged with the same 0.1 C-rate to 3V after the simplified battery has rested for 30 minutes. Noticeably, the 0.1 C-rate represents the simplified battery can be fully charged after 10 hours. Accordingly, in the simplified battery, when the OCV equals 4.1 V, the SOC is 100%; when the OCV equals 3.8 V, the SOC is 47%; and when the OCV equals 3.0 V, the SOC is 0%.

However, the simplified battery can only be applied to the above OCV range from 3.0V to 4.1V, which lacks of flexibility for the look-up table to be utilized for various OCV ranges. For example, when the user needs to precisely estimate another chargeable battery with an OCV range from 3.6V to 4.0V, the mentioned look-up table will not qualify for the different OCV range. Therefore, it has become an important issue to adaptively provide a universal method and computer system for measuring a remaining battery capacity of the mobile device.

### SUMMARY OF THE INVENTION

It is therefore an objective of the invention to provide a universal method and computer system for measuring a remaining battery capacity of the mobile device.

The present invention discloses a method for measuring a remaining capacity of a chargeable magnetic material comprises determining a discharging parameter, obtaining an open-circuit-voltage state-of-charge (OCV SOC) curve according to the discharging parameter, obtaining a discharging curve according to the OCV SOC curve and the discharging parameter, and processing an interpolation operation to measure the remaining capacity according to the OCV SOC curve and the discharging curve.

The present invention discloses another computer system comprising a central processing unit, a storage device for storing a program code, wherein the program code is utilized to instruct the central processing unit to correspondingly operate a method for measuring a remaining capacity of a chargeable magnetic material coupled to the computer system. The method comprises determining a discharging parameter, obtaining an open-circuit-voltage state-of-charge (OCV SOC) curve according to the discharging parameter, obtaining a discharging curve according to the OCV SOC curve and the discharging parameter, and processing an interpolation operation to measure the remaining capacity according to the OCV SOC curve and the discharging curve.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a schematic diagram of a conventional OCV simplified circuit.

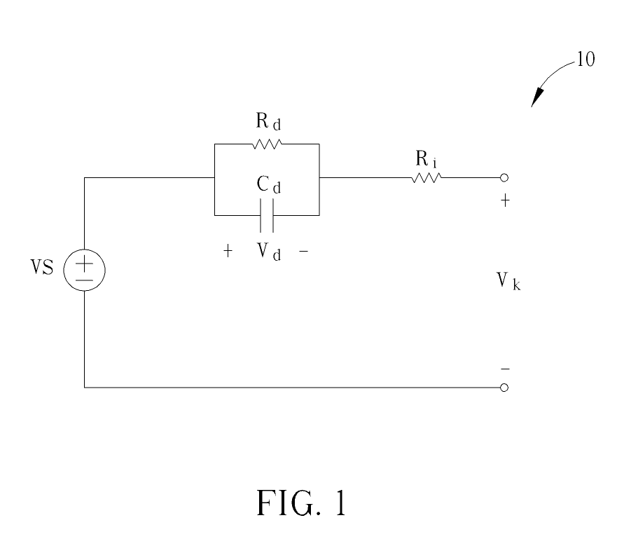

FIG. 2 illustrates a schematic diagram of a relationship curve between a plurality of OCV values and a plurality of SOC values according to the prior art.

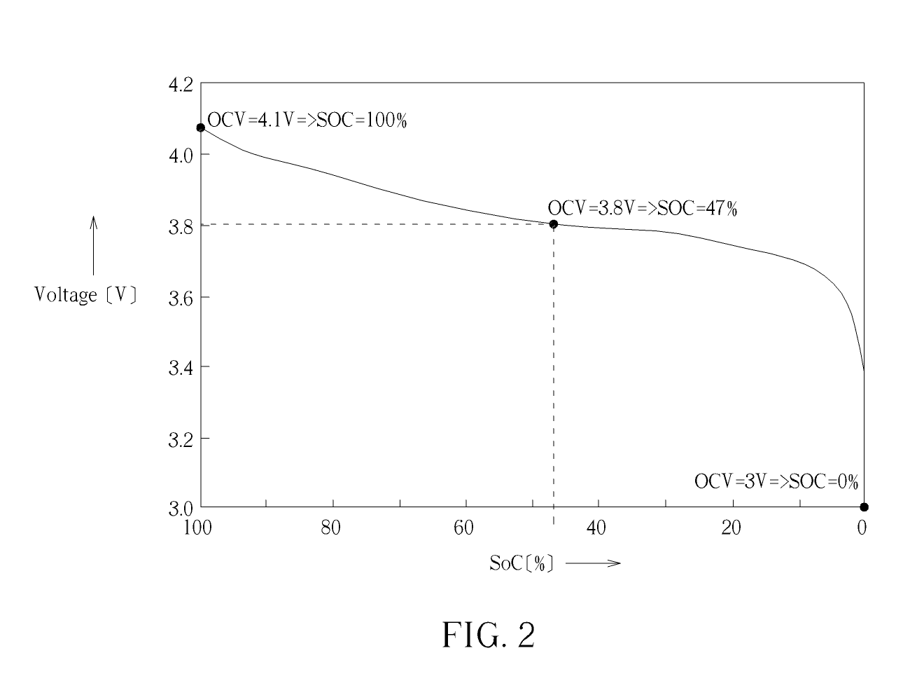

FIG. 3 illustrates a schematic diagram of a computer system according to an embodiment of the invention.

FIG. 4 illustrates a flow chart of a measurement process according to an embodiment of the invention.

FIG. 5 illustrates a flow chart of a depicting process according to an embodiment of the invention.

FIG. 6 illustrates a schematic diagram of the OCV SOC curve and the discharging curve according to an embodiment of the invention.

FIG. 7 illustrates a flow chart of a interpolation process according to an embodiment of the invention.

FIG. 8 illustrates a schematic diagram of a representative transformation from the original SOC value to the transformed SOC value according to an embodiment of the invention.

### DETAILED DESCRIPTION

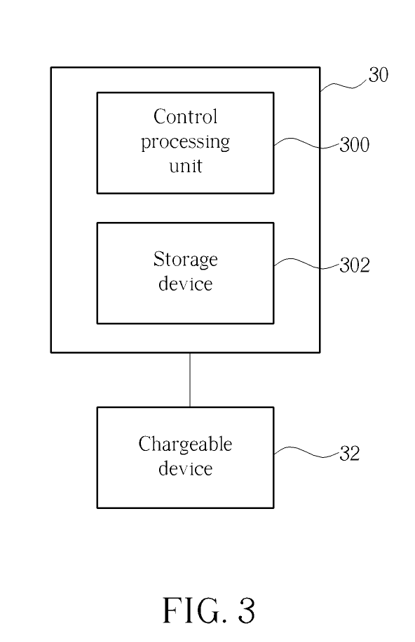

Please refer to FIG. 3, which illustrates a schematic diagram of a computer system 30 according to an embodiment of the invention. As shown in FIG. 3, the computer system 30 comprises a central processing unit 300 and a storage device 302. Also, the computer system 30 is coupled to a chargeable device 32. In detail, the storage device 302 stores a program code, which is utilized to instruct the central processing unit 300 to correspondingly operate a method for measuring a remaining capacity of a chargeable device 32. The chargeable device 32 is a chargeable magnetic material, such as the lithium-ion battery or other similar rechargeable batteries. In the embodiment, the connection between the computer system 30 and the chargeable device 32 may be realized via a wireless signal transmission interface or a wired signal transmission interface, such as USB, which is not limiting the scope of the invention. Due to the connection, the chargeable device 32 may also be charged via the computer system 30 as a stable voltage source. In the meanwhile, the computer system 30 can instantaneously measure the remaining capacity of the chargeable device 32, so as to process a wireless/wired charging operation for the chargeable device 32. Alternatively, the computer system 30 may be utilized to operate the method for measuring the remaining capacity only, and the chargeable device 32 is charged via another plug-in power source (not shown in the figure). Once the computer system 30 determines that the chargeable device 32 is at a predetermined lower status of the remaining capacity, the computer system 30 will correspondingly initiate the wired charging operation between the plug-in power source and the chargeable source 32, which is also within the scope of the invention.

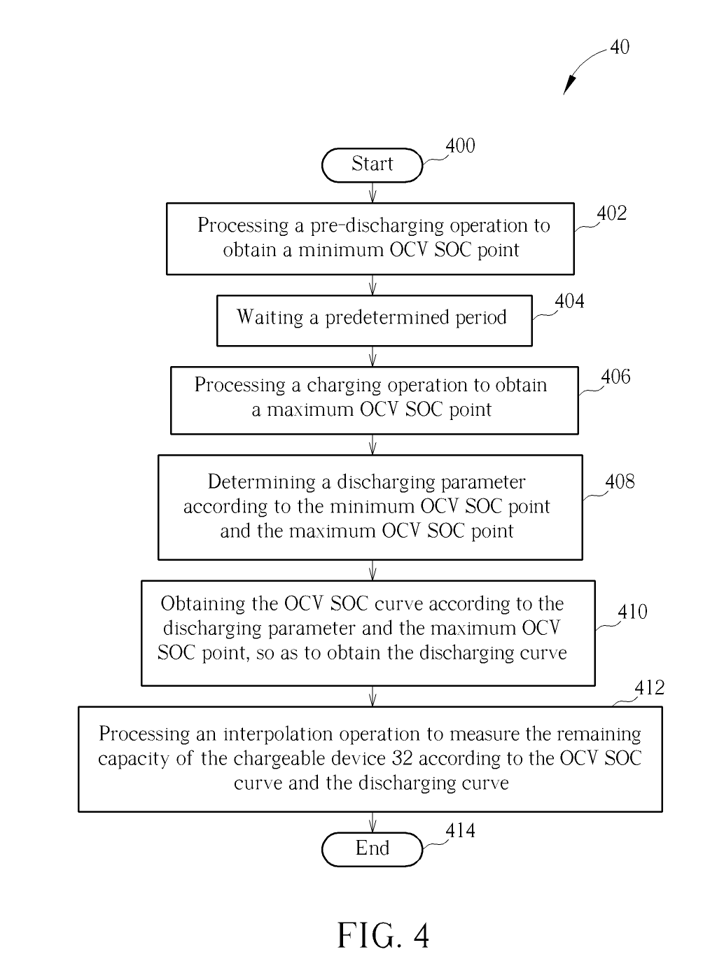

Preferably, the method implemented by the program code stored in the storage device 302 for measuring the remaining capacity of the chargeable device 32 can be summarized as a measurement process 40 to simultaneously obtain an open-circuit-voltage state-of-charge (OCV SOC) curve and a discharging curve, as shown in FIG. 4. The measurement process 40 includes, but not limited to, the steps as follows.

Step 400: Start.

Step 402: Processing a pre-discharging operation to obtain a minimum OCV SOC point.

Step 404: Waiting a predetermined period.

Step 406: Processing a charging operation to obtain a maximum OCV SOC point.

Step 408: Determining a discharging parameter according to the minimum OCV SOC point and the maximum OCV SOC point.

Step 410: Obtaining the OCV SOC curve according to the discharging parameter and the maximum OCV SOC point, so as to obtain the discharging curve.

Step 412: Processing an interpolation operation to measure the remaining capacity of the chargeable device 32 according to the OCV SOC curve and the discharging curve.

Step 414: End.

In the embodiment, the measurement process 40 which processes the interpolation operation via the OCV SOC curve and the discharging curve is utilized to build a measurement look-up table of different types of the chargeable device 32 once the chargeable device 32 is produced to be delivered away from factories for consumers. Accordingly, the computer system 30 may measure the remaining capacity of the chargeable device 32 according to the measurement look-up table. Also, the user may utilize the measurement process 40 to set up different measurement look-up tables corresponding to different chargeable devices comprising different operational voltage ranges, so as to accurately measure the remaining capacity of different types of chargeable device. In comparison with the prior art, the measurement process 40 cooperating with the computer system 30 may be applied to all kinds of chargeable devices to render better application and measurement of remaining capacity.

In detail, in step 402, once the chargeable device 32 is coupled to the computer 30, the pre-discharging operation is performed to discharge the remaining power of the dischargeable device 32, so as to obtain the minimum OCV SOC point. In step 404, after the chargeable device 32 is discharged to run out of the remaining power, the computer system 30 will stop any related power interchange with the chargeable device 32, so as to wait for the predetermined period, such as 30 minutes, which can avoid an over-discharging operation of the chargeable device 32. In step 406, after the predetermined period, the computer system 30 processes the charging operation for the chargeable device 32, so as to obtain the maximum OCV SOC point. Preferable, after the charging operation, the computer system 30 may wait for another predetermined period to avoid an over-charging operation of the chargeable device 32, which is not limiting the scope of the invention.

In step 408, the discharging parameter can be determined according to the minimum OCV SOC point and the maximum OCV SOC point. In other words, the user can adaptively choose how many measurement points (steps) he/she requires between the minimum OCV SOC point and the maximum OCV SOC point, so as to determine the discharging parameter. In the embodiment, the discharging parameter is 0.5 C-rate to correspondingly obtain 19 measurement points (or 20 steps) between the minimum OCV SOC point and the maximum OCV SOC point, and the invention is not limited thereto.

In step 410, the computer system 30 simultaneously depicts the OCV SOC curve as well as the discharging curve according to the discharging parameter as well as the maximum/minimum OCV SOC point. In step 412, the computer system 30 processes the interpolation operation, which can further be complied to be the program code stored in the storage device 302 according to the OCV SOC curve as well as the discharging curve, so as to measure the remaining capacity of the chargeable device 32.

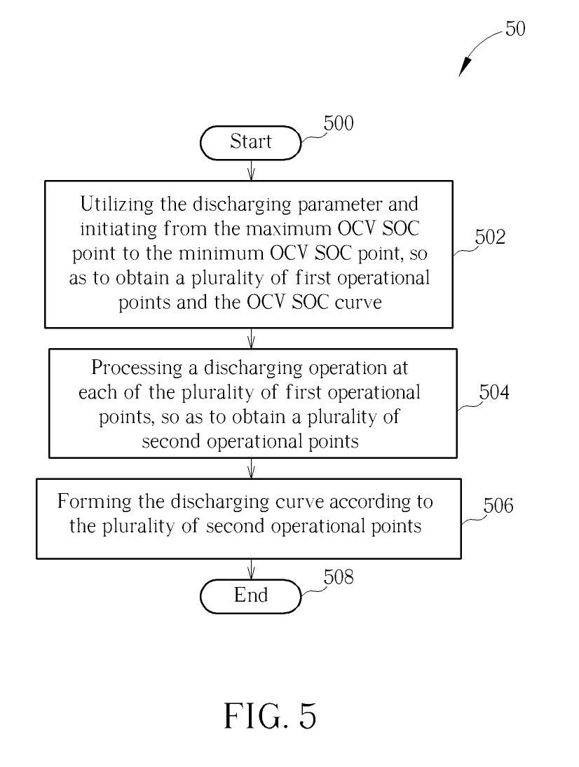

Furthermore, step 410 of the measurement process 40 can also be summarized as a depicting process 50 to simultaneously obtain the OCV SOC curve and the discharging curve, as shown in FIG. 5. The depicting process 50 includes, but not limited to, the steps as follows.

Step 500: Start.

Step 502: Utilizing the discharging parameter and initiating from the maximum OCV SOC point to the minimum OCV SOC point, so as to obtain a plurality of first operational points and the OCV SOC curve.

Step 504: Processing a discharging operation at each of the plurality of first operational points, so as to obtain a plurality of second operational points.

Step 506: Forming the discharging curve according to the plurality of second operational points.

Step 508: End.

In step 502, the plurality of first operational points initiated from the maximum OCV SOC point to the minimum OCV SOC point are obtained according to the discharging parameter, so as to form the OCV SOC curve by connecting the plurality of first operational points together. In step 504, each of the plurality of first operational points is processed the discharging operation, wherein the discharging operation can utilize the same discharging parameter as mentioned in the above or choose another particular value according to different users' requirements. Accordingly, the plurality of second operational points are obtained after the discharging operation, and each of the plurality of the second operational points corresponds to one of the plurality of first operational points, respectively, i.e. each of the plurality of the second operational points is derived from each of the plurality of the first operational points. Noticeably, the embodiment is not limiting the sequential generation of each of the plurality of first/second operational points. Hereinafter, if the first operational points are P1-Pn and the second operational points are Q1-Qn, the embodiment is demonstrated to have the sequential generation as P1, Q1, P2, Q2, . . . Pn, Qn, and is not limiting the scope of the invention. In step 506, the discharging curve is obtained via connecting the plurality of second operational points together. Certainly, the number of the plurality of first/second operational points is determined by the discharging parameter. If the user needs to increase/decrease the number of the plurality of first/second operational points, the user can adaptively adjust the value of the discharging parameter, which is also within the scope of the invention.

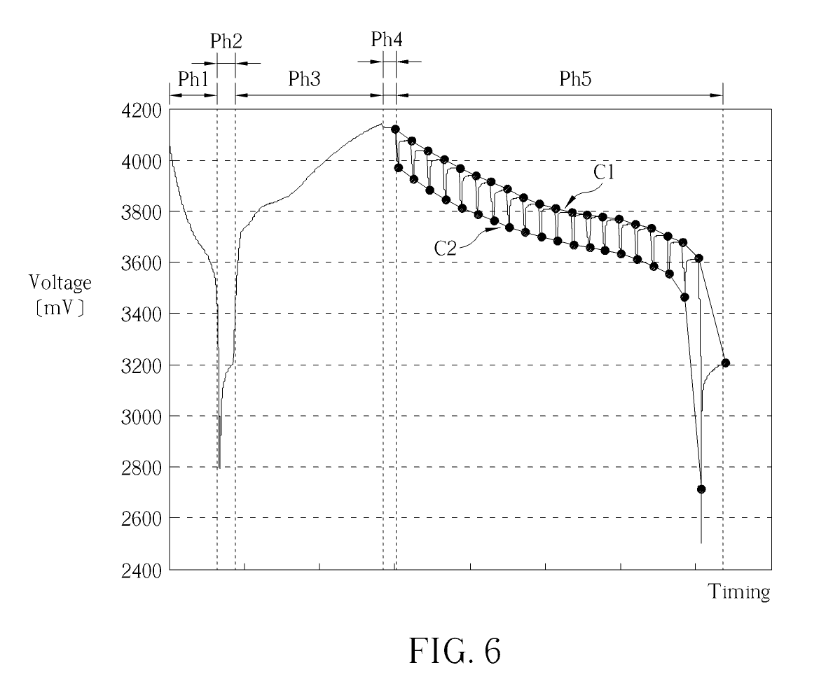

Additionally, please refer to FIG. 6, which illustrates a schematic diagram of the OCV SOC curve C1 and the discharging curve C2 according to an embodiment of the invention. Noticeably, the embodiment demonstrates the combination of the OCV SOC curve C1 and the discharging curve C2 for simple clarification, and those skilled in the art can adaptively add more than one charging/discharging curves cooperating with the OCV SOC curve C1 to obtain different upper/lower limitation values, respectively, so as to obtain different operational points along the charging/discharging curves, which is also in the scope of the invention. As shown in FIG. 6, the embodiment of the invention can be classified into different operational phases to correspond to the different steps of the measurement process 40 at different periods. Briefly, step 402 is operated at a phase Ph1, step 404 is operated at a phase Ph2, step 406 is operated at a phase Ph3, and step 410 is operated at a phase Ph5. Noticeably, step 408 may be operated before the phase ph5, and step 412 may be operated after the phase ph5. In the embodiment, a phase ph4 is correspondingly added to avoid the over-charging operation, and those skilled in the art can adaptively adjust the practical number of phases, so as to eliminate the phase Ph4 to have the phase Ph5 be directly operated after the phase Ph3, which is also within the scope of the invention. At the phase ph5, the OCV SOC curve C1 is demonstrated with the 19 first operational points, and the discharging curve C2 is demonstrated with the 19 second operational points. After the OCV SOC curve C1 and the discharging curve C2 are formed, the relationship curve (i.e. the measurement look-up table) between the SOC values and the OCV values is correspondingly set up, and the remaining capacity of the chargeable device 32 will be accurately obtained as follows.

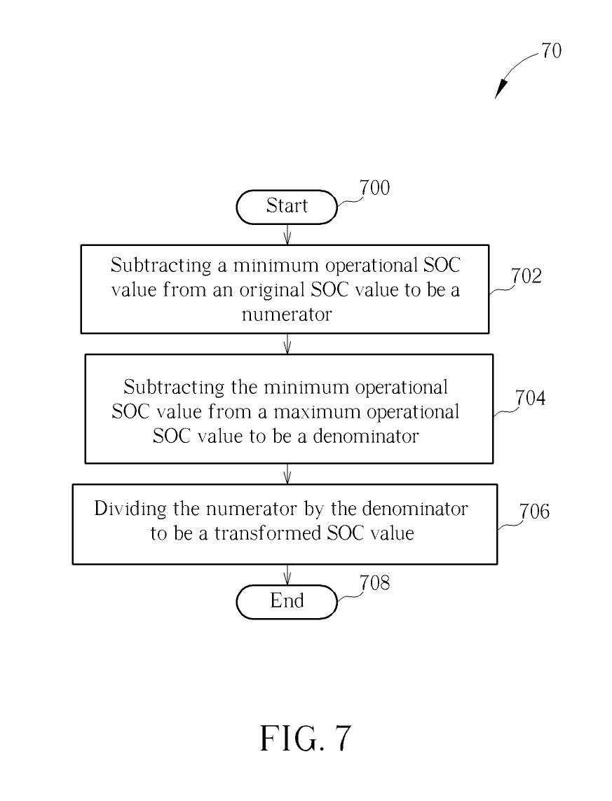

Furthermore, step 412 of the measurement process 40 can also be summarized as an interpolation process 70, as shown in FIG. 7. The interpolation process 70 includes the steps as follows.

Step 700: Start.

Step 702: Subtracting a minimum operational SOC value from an original SOC value to be a numerator.

Step 704: Subtracting the minimum operational SOC value from a maximum operational SOC value to be a denominator.

Step 706: Dividing the numerator by the denominator to be a transformed SOC value.

Step 708: End.

According to the interpolation process 70, the computer system 30 may receive a control signal (not shown in the figure) from the user, such as from an interactive keyboard or mouse, so as to be adaptively inputted a user-defined operational voltage range. Also, the computer system 30 may actively determine the operational voltage range, which corresponds to characteristics of the chargeable device 32, once the chargeable device 32 is coupled to the computer system 30. Preferably, the operational voltage range may match onto the discharging curve with the minimum voltage value and the maximum voltage value, and the operational voltage range may also match onto the OCV SOC curve to have the minimum operational SOC value and the maximum operational SOC value, respectively. In other words, the minimum operational SOC value corresponds to the minimum voltage value, and the maximum operational SOC value corresponds to the maximum voltage value. Besides, a current OCV value of the chargeable device 32 is measured while the chargeable device is coupled to the computer system 30, and the current OCV value also corresponds to the original SOC value along the discharging curve. Under such circumstances, in step 702, the numerator is obtained via subtracting the minimum operational SOC value from the original SOC value. In step 704, the denominator is obtained via subtracting the minimum operational SOC value from the maximum operational SOC value. In step 706, the transformed SOC value of the chargeable device 32 is obtained via dividing the numerator by the denominator. Consequently, the transformed SOC value can be utilized to represent the remaining capacity of the chargeable device 32, so as to determine whether the computer system 30 operates the wireless/wired charging operation for the chargeable device 32.

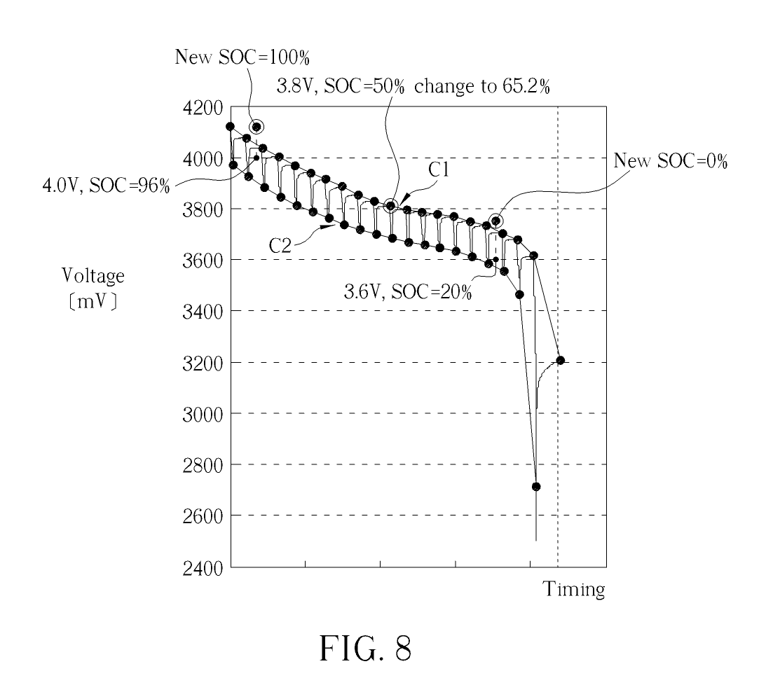

Please refer to FIG. 8, which illustrates a schematic diagram of a representative transformation from the original SOC value to the transformed SOC value according to an embodiment of the invention. As shown in FIG. 8, in the embodiment, the operational voltage range is from 3.6V to 4.0V such that the minimum operational SOC value is 20% and the maximum operational SOC value is 96%. After the chargeable device 32 is coupled to the computer system 30, the current OCV value is obtained as 3.8V to correspondingly render the original SOC value. After processing the interpolation process 70 with the calculation (50−20)/(96−20)=65.2%, the transformed SOC value is obtained as 65.2%. Therefore, the user can arbitrarily choose different operational voltage ranges of different chargeable devices, and accordingly, obtain the transformed SOC value according to the OCV SOC curve, the discharging curve and the interpolation process 70. In comparison with the prior art, the embodiment of the invention applies to all kinds of operational voltage ranges to accurately measure the remaining capacity after the interpolation process, so as to provide an indication signal (not shown in the figure) to inform the computer system 30 (or the user) when to process the wireless/wired charging operation for the chargeable device 32.

Noticeably, the measurement process 40, the depicting process 50 and the interpolation process 70 may all be compiled to be one program code stored in the storage device 302. In addition, the mechanism for determining whether the computer system 30 processes the wireless/wired charging operation for the chargeable device 32 may also be compiled to be the same or another program code, and the program code will be operated via the processing unit 300 after finish the measurement process 40, the depicting process 50 and the interpolation process 70, which is also within the scope of the invention.

In summary, the invention provides a method and computer system to measure the remaining capacity of the chargeable device. By utilizing the OCV SOC curve and the discharging curve, an interpolation process can be operated to obtain a transformation between the original SOC value and the transformed SOC value, so as to accurately measure the remaining capacity. In comparison with the prior art, the embodiment of the invention can be directly applied to all kinds of chargeable devices with various operational voltage ranges, so as to improve the application range.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A method for measuring a remaining capacity of a chargeable magnetic material, the method comprising:
determining a discharging parameter;
obtaining an open-circuit-voltage state-of-charge (OCV SOC) curve according to the discharging parameter;
obtaining a discharging curve according to the OCV SOC curve and the discharging parameter; and
processing an interpolation operation to measure the remaining capacity according to the OCV SOC curve and the discharging curve.

2. The method of claim 1, wherein the step of obtaining the OCV SOC curve according to the discharging parameter further comprises:
processing a pre-discharging operation to obtain a minimum OCV SOC point;
processing a charging operation to obtain a maximum OCV SOC point; and
obtaining the OCV SOC curve according to the discharging parameter, the minimum OCV SOC point and the maximum OCV SOC point.

3. The method of claim 2, wherein the step of processing the charging operation to obtain the maximum OCV SOC point further comprises:
waiting a predetermined period after processing the pre-discharging operation for obtaining the minimum OCV SOC point.

4. The method of claim 2, the step of obtaining the discharging curve according to the OCV SOC curve and the discharging parameter further comprises:
utilizing the discharging parameter, the minimum OCV SOC point and the maximum OCV SOC point to obtain the discharging curve.

5. The method of claim 4, further comprising:
utilizing the discharging parameter and initiating from the maximum OCV SOC point to the minimum OCV SOC point to obtain a plurality of first operational points along the OCV SOC curve;
processing a discharging operation at each of the plurality of first operational points to obtain a plurality of second operational points; and
forming the discharging curve according to the plurality of second operational points.

6. The method of claim 1, wherein the step of processing the interpolation operation to measure the remaining capacity according to the OCV SOC curve and the discharging curve further comprises:
selecting a target voltage value on the discharging curve and correspondingly obtaining an original SOC value on the OCV SOC curve;
selecting an operational voltage range on the discharging curve and correspondingly obtaining an original SOC range on the OCV SOC curve; and
processing the interpolation operation according to the original SOC value and the original SOC range, so as to obtain a transformed SOC value to measure the remaining capacity.

7. The method of claim 6, wherein the operational voltage range corresponds to characteristics of a chargeable magnetic material.

8. The method of claim 6, wherein the original SOC range comprises a minimum operational SOC value and a maximum operational SOC value.

9. The method of claim 8, wherein the interpolation operation further comprises:
subtracting the minimum operational SOC value from the original SOC value to be a numerator;
subtracting the minimum operational SOC value from the maximum operational SOC value to be a denominator; and
dividing the numerator by the denominator to be the transformed SOC value.

10. A computer system comprising:
a central processing unit;
a storage device for storing a program code, wherein the program code is utilized to instruct the central processing unit to correspondingly operate a method for measuring a remaining capacity of a chargeable magnetic material coupled to the computer system, the method comprising:
determining a discharging parameter;
obtaining an open-circuit-voltage state-of-charge (OCV SOC) curve according to the discharging parameter;
obtaining a discharging curve according to the OCV SOC curve and the discharging parameter; and
processing an interpolation operation to measure the remaining capacity according to the OCV SOC curve and the discharging curve.

11. The computer system of claim 10, wherein the step of obtaining the OCV SOC curve according to the discharging parameter further comprises:
processing a pre-discharging operation to obtain a minimum OCV SOC point;
processing a charging operation to obtain a maximum OCV SOC point; and
obtaining the OCV SOC curve according to the discharging parameter, the minimum OCV SOC point and the maximum OCV SOC point.

12. The computer system of claim 11, wherein the step of processing the charging operation to obtain the maximum OCV SOC point further comprises:
waiting a predetermined period after processing the pre-discharging operation for obtaining the minimum OCV SOC point.

13. The computer system of claim 11, wherein the step of obtaining the discharging curve according to the OCV SOC curve and the discharging parameter further comprises:
utilizing the discharging parameter, the minimum OCV SOC point and the maximum OCV SOC point to obtain the discharging curve.

14. The computer system of claim 13, wherein the step of utilizing the discharging parameter, the minimum OCV SOC point and the maximum OCV SOC point to obtain the discharging curve further comprises:
utilizing the discharging parameter and initiating from the maximum OCV SOC point to the minimum OCV SOC point to obtain a plurality of first operational points along the OCV SOC curve;
processing a discharging operation at each of the plurality of first operational points to obtain a plurality of second operational points; and
forming the discharging curve according to the plurality of second operational points.

15. The computer system of claim 10, wherein the step of processing the interpolation operation to measure the remaining capacity according to the OCV SOC curve and the discharging curve further comprises:
selecting a target voltage value on the discharging curve and correspondingly obtaining an original SOC value on the OCV SOC curve;
selecting an operational voltage range on the discharging curve and correspondingly obtaining an original SOC range on the OCV SOC curve; and
processing the interpolation operation according to the original SOC value and the original SOC range, so as to obtain a transformed SOC value to measure the remaining capacity.

16. The computer system of claim 15, wherein the operational voltage range corresponds to characteristics of a chargeable magnetic material.

17. The computer system of claim 15, wherein the original SOC range comprises a minimum operational SOC value and a maximum operational SOC value.

18. The computer system of claim 17, wherein the interpolation operation further comprises:
subtracting the minimum operational SOC value from the original SOC value to be a numerator;
subtracting the minimum operational SOC value from the maximum operational SOC value to be a denominator; and
dividing the numerator by the denominator to be the transformed SOC value.
